(19) United States
(12) Patent Application Publication
(10) Pub. No.: US 2012/0012177 A1
(43) Pub. Date: Jan. 19, 2012

(54) HIGH EFFICIENT DYE-SENSITIZED SOLAR CELLS USING TiO2-MULTIWALLED CARBON NANO TUBE (MWCNT) NANOCOMPOSITE

(76) Inventors: Subas Kumar Muduli, Maharashtra (IN); Vivek Vishnu Dhas, Maharashtra (IN); Sarfraj Hisamuddin, Maharashtra (IN); Mujawar, Maharashtra (IN); Satishchandra Balkrishna Ogale, Maharashtra (IN)

(21) Appl. No.: 13/143,964

(22) PCT Filed: Jan. 12, 2010
(86) PCT No.: PCT/IN10/00023

§ 371 Date: Sep. 27, 2011

(30) Foreign Application Priority Data
Jan. 12, 2009 (IN) 48/DEL/2009

(51) Int. Cl. H01L 31/0224; B05D 5/12; B05D 3/02; B01J 21/18; B05D 3/12; B82Y 40/00; B82Y 99/00

(52) U.S. Cl. 136/256; 502/182; 427/74; 977/948; 977/752; 977/847

(57) ABSTRACT

The invention provides high efficient dye-sensitized solar cells using tio₂-carbon nano tube (MWCNT) nanocomposite. More particularly, the invention provides TiO₂-MWCNT nanocomposites prepared by hydrothermal route which result in higher efficiency of the dye sensitized solar cell.

### FIELD OF THE INVENTION

The invention relates to high efficient dye-sensitized solar cells using TiO₂-carbon nano tube (MWCNT) nanocomposite.

More particularly, the invention relates to TiO₂-MWCNT nanocomposites prepared by hydrothermal route which result in higher efficiency of the dye sensitized solar cell.

### BACKGROUND OF THE INVENTION

The solar cell performance in dye sensitized or hybrid solar cells is adversely affected by the low efficiency of transfer of photo-generated charges to the electrodes. CNT can provide direct and efficient path for such photo generated electrons, hence composites of CNT with metal oxides have been proposed. Sol-gel and electrophoresis methods to synthesize TiO₂-MWCNT nanocomposites have been attempted, but the physical and electronic attachment between TiO₂ nanoparticles and the CNT does not seem to be strong enough in these cases, such that it can prevent recombination of the photo-generated charges strongly.

An article titled “Hydrothermal preparation of ZnO:CNT and TiO₂:CNT composites and their photocatalytic applications” by K. Byrappa, A. S. Dayananda et.al., published in Journal of Material Science (2008) 43:2348-2355, DOI 10.1007/s10853-007-1989-8 dated Feb. 21, 2008 discloses ZnO:CNT and TiO₂:CNT composites (having multiwalled carbon nanotube (MWCNT)) which were fabricated under mild hydrothermal conditions (T=150-240° C.) with an autogenous pressure. Photocatalytic applications of the composites towards sunlight as well as UV light were investigated using indigo caramine dye.

An article “Preparation and characterization of new photocatalyst combined MWCNTs with TiO₂ nanotubes” by ZHU Zhi-ping et. al., published on Sep. 10, 2007 Trans. Nonferrous Met. Soc. China 17(2007) s1117-1121 discloses new type of photocatalysts MWCNTs/TiO₂-NTs nanocomposites prepared by combining multi-walled carbon nanotube (MWCNTs) with TiO₂-derived nanotubes were synthesized by a modified hydrothermal method.

Another article titled “Hydrothermal Synthesis of Nanorods/Nanoparticles TiO₂ for Photocatalytic Activity and Dyesensitized Solar Cell Applications” by Sorapong Pavasupree et. al., published in Materials Research Society discloses Nanorods/nanoparticles TiO₂ with mesoporous structure synthesized by hydrothermal method at 150° C. for 20 h. The solar energy conversion efficiency of the cell using nanorods/nanoparticles TiO₂ with mesoporous structure was about 7.12%.

Lee T. Yet al in Thin Solid Films, 2007 (Vol 515), Page 5131 discloses fabrication of dye sensitized solar cell using TiO2 coated multiwalled carbon nanotubes (MWCNT) by sol-gel method with 0.1 wt % of MWCNT and thickness of 10-15 microns with efficiency of 4.97%.

Thus there is a need in the art to provide for a composition of metal oxide-CNT composites and a process of synthesis for said composite such that it results in effective charge transfer process, leading to improved solar cell efficiency. It has been surprisingly found by the inventors that the hydrothermal route to synthesize TiO₂-CNT nano composites improves the performance of solar cells by greater than 5% and such an improvement is not reported in the art.

### SUMMARY OF THE INVENTION

Accordingly, present invention provides a hydrothermal process for the preparation of Titanium dioxide-Multi-walled carbon nanotubes (TiO₂-MWCNT) nanocomposite, and the said process comprising the steps of:
i. hydrolyzing Titanium compound precursor in water;

ii. sonicating hydrolysed presoursor of step (a) with MWCNTs;
iii. transferring product of step (b) to autoclave vessel with H₂SO₄ and kept at 150-200° C. for 12-24 hours;
iv. washing product of step (c) with water; and
v. drying the product of step (d) at about 50-60° C. in dust proof environment to obtain TiO₂-CNT nanocomposite.

In an embodiment, the present invention provides titanium precursor/compound which is hydrolysable at room temperature, preferably 20-30° C., preferably titanium isopropoxide or titanuim chloride.

In another embodiment, the present invention provides Titanium dioxide-Multi-walled carbon nanotubes (TiO₂-MWCNT) nanocomposite prepared by the hydrothermal process wherein the wt % of CNT with respect to TiO₂ in the nanocomposite used is in the range of 0.01-0.5 wt %.

In yet another embodiment, the present invention provides titanium dioxide-Multi-walled carbon nanotubes (TiO₂-MWCNT) nanocomposite prepared by the hydrothermal process, wherein the thickness of said nanocomposite film is 1-15 microns.

In still another embodiment, the present invention provides a process for the preparation of a solar cell using Titanium dioxide-Multi-walled carbon nanotubes (TiO₂-MWCNT) nanocomposite, wherein the said process comprising the steps of:
I. putting 200 microlitre drops of the TiO₂-CNT nanocomposite as obtained in step (v) of claim 1 on Flourine doped tin oxide conductive and hydrolyzed glass substrate;
II. controlling the thickness of the film with 0.5 micron-thick scotch tape; forming film by doctor-blading process;
III. heat treating the film as obtained in step (h) at a temperature of 450° C. for 1 h.
IV. sensitizing TiO₂-CNT nanocomposite film as obtained in step (i) with standard ruthenium-based N3-dye to obtain dye sensitized TiO₂-CNT nanocomposite film;
V. preparing electrode by using dye sensitized TiO₂-CNT nanocomposite film as obtained in step (j);
VI. prepareing dye sensitized TiO₂-CNT nanocomposite solar cell by using electrode as obtained in step (k), counter electrode and liquid electrolyte.

In yet another embodiment of the present invention, counter electrode used is platinum-coated FTO (Pt—FTO) substrate.

In yet another embodiment of the present invention, liquid electrolyte consisting of 0.1 M lithium iodide, 0.05M iodine in acetonitrile.

In yet another embodiment of the present invention, the improved efficiency of solar cell ranges between 5-15%.

In still another embodiment of the present invention, efficiency of solar cell is greater than 5%.

### BRIEF DESCRIPTION OF THE DRAWINGS

FIG. 1: Transmission Electron Microscopy (TEM), Field-Emission Scanning Electron Microscope (FE-SEM, Hitachi S-4200) images of Titanium di-oxide and MWCNTs nano composites of the invention prepared by the hydrothermal process. Figure la shows the Transmission Electron Microscopy (TEM) image of TiO₂ nanoparticles synthesized by the hydrothermal process without incorporation of MWCNT. The mean particle size is about 8-10 nm and the particles are faceted suggesting good crystallinity in the hydrothermal process. Figure lb shows TEM image of MWCNTs used in the experiment indicating its dimensions (Diameter ˜20-40 nm and length ˜5-15 μm). The integration between MWCNT and TiO₂ is seen from the Field-Emission Scanning Electron Microscope (FE-SEM) data shown in FIG. 1c. A uniform growth with excellent TiO₂ NPs coverage can be clearly seen.

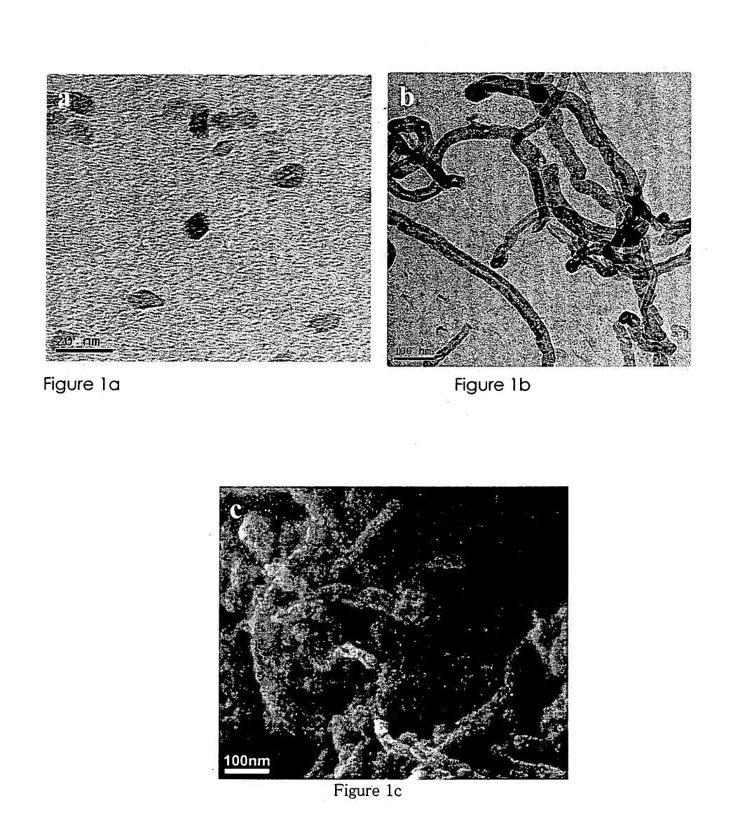

FIG. 2: FT-IR spectrum of Titanium di-oxide and MWCNTs nano composites of the invention prepared by the hydrothermal process. FIG. 2a shows the FTIR data of (a) pristine MWCNTs, (b) TiO₂ nanoparticles, (c) hydrothermally processed MWCNTs and (d) TiO₂-MWCNTs nanocomposites. The bonding between Ti-O is clearly represented in the region near 500 cm⁻¹. It is interesting to note from the black and red arrows in this region that the mean position of the signature shifts from about 520 cm⁻¹ in the TiO₂ case to about 612 cm⁻¹ for the TiO₂-MWCNT composite. This can be attributed to different size distributions and possibly levels of strains in the two cases. In the cases of hydrothermally processed samples involving MWCNT only (namely, MWCNT and TiO₂-MWCNT) we note clear signatures centered near 1143 cm⁻¹ and 1735 cm⁻¹. The signature near 1143 cm⁻¹ is in the fingerprint region, hence difficult to assign uniquely. However, the occurrence of the signature near 1735 cm⁻¹ (see circled region) with contribution in the region around 3400 cm⁻(OH stretch, which also overlaps with other contributions) together indicate the presence of —COOH group only in the hydrothermally processed cases involving MWCNT. From FIG. 2b it can be noted that in the TiO₂-MWCNT nanocomposite the same signature appears a bit shifted to 1745 cm⁻¹, suggesting the effect of conjugation of TiO₂ on the modified MWCNT surface. Other characteristic bands including the sharp one near 1380 cm⁻¹ are generated due to different mineralizer residues used in the hydrothermal process.

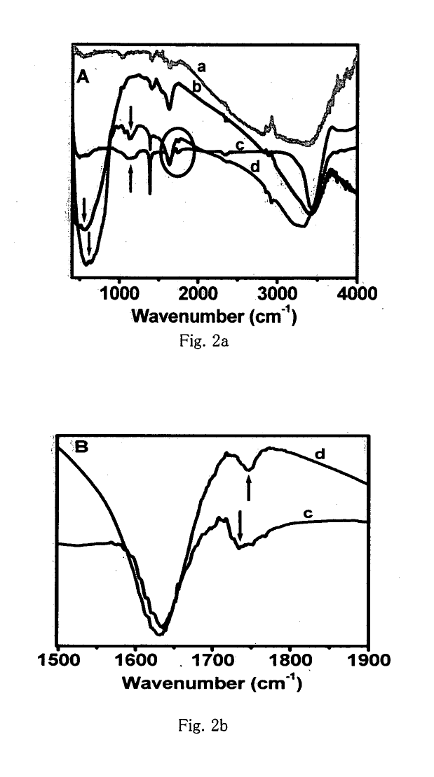

### DETAIL DESCRIPTION OF THE INVENTION

Accordingly, present invention provides a composition comprising nanocomposites of Titanium dioxide and carbon nanotubes (CNT) prepared by hydrothermal process. The TiO₂-CNT nanocomposites of the invention are prepared by the hydrothermal route. The TiO₂-CNT nanocomposites of the invention prepared by the hydrothermal route are used for improvement of efficiency of solar cells to greater than 5%.

The hydrothermal process of preparation of the composition of the invention comprises a Ti compound/precursor. The Ti compound/precursor, preferably are titanium isopropoxide or titanuim chloride and such which are hydrolysable at room temperature, particularly 20-30° C. The CNT of the invention are preferably multi-walled.

The TiO₂-CNT nanocomposites of the invention are prepared by the hydrothermal process comprising:
(a) hydrolyzing Titanium compound/precursor in water;
(b) sonicₐting presoursor of step (a) with CNTs;
(c) transferring procduct of step (b) to autoclave vessel with H₂SO₄ and kept at 150-200° C. for 12-24 hours;
(d) washing product of step (c)with water, and
(e) drying the product of step (d)at about 50-60 deg C. in dust proof environment.

The wt % of CNT with respect to TiO₂ is in the range of 0.01-0.5 wt %. Sulphuric acid is added in the range of 2-5 ml. The autoclave vessel is preferably Teflon coated and the process is carried out at 150-200 deg C. for 12-24 hours. The product hence obtained is dried at 50-60 deg C.

The CNTs of the invention are optionally modified by chemical processes selected from acid treatment, base treatment, organic, organometallic attachment and such like and physical processing selected from mechanical, thermal, plasma, radiation treatment and such like.

The TiO₂-CNT nanocomposites of the invention are characterized by Transmission Electron Microscope (TEM), Field-Emission Scanning Electron Microscope (FE-SEM) and FT-IR spectroscopy. The FTIR data suggest that the —COOH groups open up on the surface of

MWCNT under hydrothermal processing conditions and these conjugate with the Ti precursor to yield a composite. This integral conjugation is effective in the charge transfer process. This efficient charge transfer from TiO₂ to MWCNT and the efficient electron transport by the latter improves the efficiency of the solar cell by greater than 5%, thus achieving the objective of the invention of improving performance of solar cells.

The nanocomposite of the invention prepared by the hydrothermal process improve the efficiency of the solar cells to greater than 5% as exemplified herein. In comparison to Lee et al wherein the TiO₂-CNT nanocomposites prepared by sol-gel method gave maximum solar cell efficiency of 4.97% and Pavasupree et at wherein nanorods and nanoparticles of TiO₂ with mesoporous structures gave an efficiency of 7.12%, the TiO₂-CNT nanocomposites prepared by hydrothermal process of the invention gave improved solar cell efficiency in the range of 5-15%. The thickness of the nanocomposite of the invention in the solar cell as exemplified herein is in the range of 1-20 microns and shows efficiency in the range of 5-15%.

### EXAMPLES

The present invention will be more specifically explained by following examples. However, the scope of the present invention is not limited to the scope of these examples below.

### Example 1

### Preparation of TiO₂-MWCNTs Nanocomposite

The TiO₂-MWCNTs nanocomposite was prepared by using hydrothermal method. Titanium Isopropoxide (2 ml) was hydrolyzed by adding sufficient amount of deionized water and then 5 milligrams of MWCNTs were added to the above solution followed by sonication for 5 minutes. The solution was then transferred to Teflon lined autoclave vessel along with 3 ml of H₂SO₄ (1M). This autoclave vessel was kept at 175° C. for 24 hours. The resulting product was washed thoroughly with deionized water and dried at 50° C. in a dust proof environment to produce grayish powder of TiO₂-MWCNTs nano composite.

### Example 2

### Preparation of TiO₂-CNT Nanocomposite Dye Sensitized Solar Cell

To fabricate TiO₂-CNT nanocomposite dye sensitized solar cell, the conductive glass substrates were first hydrolyzed in boiling distilled water for 30 min and air-dried. Parallel edges of each substrate were covered with 0.5 micron-thick scotch tape to control the thickness of the film. A few drops of the resultant TiO₂-CNT nanocomposite were then placed onto the (FTO) Flourine doped tin oxide substrates and the films were formed by doctor-blading process. The films were then immediately heat-treated at a temperature of 450° C. for 1 h. Before solar cell testing, the TiO₂-CNT nanocomposite films were sensitized with standard ruthenium-based N3-dye. The films were immersed in N3-dye with a concentration of 0.3 mM in ethanol for 24 hours. The samples were then rinsed with ethanol to remove excess dye on the surface and air-dried at room temperature. A spacer was placed at each edge of the TiO₂-CNT nanocomposite film electrode and the counter electrode consisting of a platinum-coated FTO (Pt—FTO) substrate was placed on top, with the Pt-coated side of each FTO substrate facing the TiO₂-CNT nanocomposite film electrode. The two electrodes were then sandwiched together with two metal clips.

An iodide-based solution was used as the liquid electrolyte, consisting of 0.1 M lithium iodide, 0.05M iodine in acetonitrile. Before analysis, drops of the liquid electrolyte were introduced to one edge of the sandwich, so that the liquid electrolyte spread in between the two electrodes. The light source was placed next to each solar cell device, allowing light to penetrate through the FTO back contact to the TiO₂-CNT nanocomposite film electrode with a constant light source intensity of ˜100 mW/cm². The resulting current-voltage curves of the cells in the dark and as a function of incident light intensity were used to derive the open-circuit voltage (Voc) and the short-circuit current density (Jsc). A spot size of 0.28 cm² was used in all measurements and was taken as the active area of each solar cell sample. The I-V characteristics as a function of incident light intensity was used to obtain the open-circuit voltage (Voc), short-circuit current density (Jsc). The values found from the I-V curves were then used to derive values for the fill factor (FF), the overall power conversion efficiency (η) for each solar cell.

### Example 3

The solar cell as fabricated with the nanocomposite as described in example 2 with thickness of about 2 μm (micrometer) with 0.12 wt % of multi walled carbon nanotubes showed an efficiency of 5.6%

### Example 4

The solar cell as fabricated with the nanocomposite as described in example 2 with thickness of about 2 μm (micrometer) with 0.25 wt % of multi walled carbon nanotubes showed an efficiency of 5.16%

### Example 5

The solar cell as fabricated with the nanocomposite as described in example 2 with thickness of 10-12 μm (micrometer) with 0.12 wt % of multi walled carbon nanotubes showed an efficiency of 7.60%.

### Example 6

The solar cell as fabricated with the nanocomposites as described in example 2 with thickness of 10-12 μm (micrometer) with 0.25 wt % of multi walled carbon nanotubes showed an efficiency of 7.37%

### ADVANTAGES OF THE INVENTION

1. The main advantage of the present invention is the use of hydrothermally synthesized TiO2-CNT nanocomposite in solar cell.
2. Another advantage of the invention is the interrelation of the thickness of the oxide layer as well as content of the CNT and its optimization to achieve the maximum conversion efficiency up to 7.6%.

We claim:

1. A hydrothermal process for the preparation of Titanium dioxide-Multi-walled carbon nanotubes (TiO₂-MWCNT) nanocomposite, and the said process comprising the steps of:
vi. hydrolyzing Titanium compound precursor in water;
vii. sonicating hydrolysed presoursor of step (a) with MWCNTs;
viii. transferring product of step (b) to autoclave vessel with H₂SO₄ and kept at 150-200° C. for 12-24 hours;
ix. washing product of step (c) with water; and
x. drying the product of step (d) at about 50-60° C. in dust proof environment to obtain TiO₂-CNT nanocomposite.

2. A hydrothermal process as claimed in claim 1, wherein said titanium precursor/compound is hydrolysable at room temperature, preferably 20-30° C., preferably titanium isopropoxide or titanuim chloride.

3. Titanium dioxide-Multi-walled carbon nanotubes (TiO₂-MWCNT) nanocomposite as prepared by the process as claimed in claim 1, wherein the wt % of CNT with respect to TiO₂ in the nanocomposite used is in the range of 0.01-0.5 wt %. Titanium dioxide-Multi-walled carbon nanotubes (TiO₂-MWCNT) nanocomposite as prepared by the process as claimed in claim 1, wherein the thickness of said nanocomposite film is 1-15 microns.

4. A process for the preparation of a solar cell using Titanium dioxide-Multi-walled carbon nanotubes (TiO₂-MWCNT) nanocomposite as claimed in claims 1 to 4, wherein the said process comprising the steps of:
I. putting 200 microlitre drops of the TiO₂-CNT nanocomposite as obtained in step (v) of claim 1 on Flourine doped tin oxide conductive and hydrolyzed glass substrate;
II. controlling the thickness of the film with 0.5 micron-thick scotch tape; forming film by doctor-blading process;
III. heat treating the film as obtained in step (h) at a temperature of 450° C. for 1 h.
IV. sensitizing TiO₂-CNT nanocomposite film as obtained in step (i) with standard ruthenium-based N3-dye to obtain dye sensitized TiO₂-CNT nanocomposite film;
V. preparing electrode by using dye sensitized TiO₂-CNT nanocomposite film as obtained in step (j);
VI. prepareing dye sensitized TiO₂-CNT nanocomposite solar cell by using electrode as obtained in step (k), counter electrode and liquid electrolyte.

6. A process as claimed in step (VII) of claim 5, wherein counter electrode used is platinum-coated FTO (Pt—FTO) substrate.

7. A hydrothermal process as claimed in claim 5, wherein liquid electrolyte consisting of 0.1 M lithium iodide, 0.05M iodine in acetonitrile.

8. A process as claimed in claim 5, wherein the improved efficiency of solar cell ranging between 5-15%.

9. Use of process as claimed in any of the preceding claims for improving efficiency of solar cell is greater than 5%.
